(19) United States
(12) Patent Application Publication
(10) Pub. No.: US 2024/0213750 A1
(43) Pub. Date: Jun. 27, 2024

(54) HOUSING CAPABLE OF INGRESS PROTECTION

(71) Applicant: Continental Automotive Systems, Inc., Auburn Hills, MI (US)

(72) Inventors: David Teteak, Crystal Lake, IL (US); David Zeiger, Mundelein, IL (US)

(73) Assignee: Continental Automotive Systems, Inc., Auburn Hills, MI (US)

(21) Appl. No.: 18/086,759

(22) Filed: Dec. 22, 2022

(51) Int. Cl. H02G 3/08; H02G 3/14

(52) U.S. Cl. CPC H02G 3/088; H02G 3/14

(57) ABSTRACT

A housing may, for example, include a housing part which may include a receiving part. The receiving part may, for example, include a first wall structure and a second wall structure. The second wall structure may be opposing the first wall structure. Moreover, the first wall structure may be shorter as compared to the second wall structure. The housing may further include a housing portion which may be coupled to the housing part. The housing part and the housing portion, when coupled, may form an enclosure which may be associated with an enclosed area within which one or more components may be carried. The component(s) may, for example, be carried in a manner such that Ingress Protection (e.g., water Ingress Protection) may be facilitated.

### BACKGROUND

A vehicle may carry one or more modules. An example of a module may be a Telematics Control unit (e.g., referable to as a Telematics module).

A telematics module may contain one or more components which may require some form/level/extent of ingress protection so as to, for example, facilitate reliability (e.g., functionality would not be adversely impacted).

Generally, a telematics module may include an enclosure which may afford some form/level/extent of ingress protection against intrusion, accidental contact and/or elements such as dust and water.

The present disclosure contemplates that currently, ingress protection may possibly not be optimally provided, and it may be helpful to address (or at least mitigate) such an issue.

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### BRIEF SUMMARY

In accordance with embodiment(s) of the disclosure, there is provided a housing. The housing may, for example, include a housing part which may include a receiving part. The receiving part may, for example, include a first wall structure and a second wall structure. The second wall structure may be opposing the first wall structure. Moreover, the first wall structure may be shorter as compared to the second wall structure. The housing may further include a housing portion which may be coupled to the housing part. The housing part and the housing portion, when coupled, may form an enclosure which may be associated with an enclosed area within which one or more components may be carried. The component(s) may, for example, be carried in a manner such that Ingress Protection (e.g., water Ingress Protection) may be facilitated.

In accordance with embodiment(s) of the disclosure, there is provided an apparatus (e.g., corresponding to a housing part) which may be used with a housing portion to form an enclosure. The enclosure may be associated with an enclosed area. Moreover, the housing portion may, for example, include one or more protrusions (e.g., at least one lip). The apparatus may include a receiving part shaped and dimensioned in a manner so as to be capable of receiving the protrusion (e.g., a lip) when the apparatus and the housing portion are coupled. The receiving part may, for example, include a first wall structure and a second wall structure. The first wall structure and the second wall structure may, for example, be spaced apart in a manner so as to define an adjoining structure. Furthermore, the first wall structure may, for example, be shorter as compared to the second wall structure. The enclosure may be shaped and dimensioned in a manner so as to carry one or more components within the enclosed area. The component(s) may be carried in the enclosed area such that Ingress Protection may be facilitated, in accordance with an embodiment of the disclosure. Ingress Protection may, for example, be in relation to at least water Ingress Protection.

Other objects, features and characteristics, as well as the methods of operation (where/if applicable) and the functions of the related elements of the structure, the combination of parts and economics of manufacture will become more apparent upon consideration of the following detailed description and appended claims with reference to the accompanying drawings, all of which form a part of this specification. It should be understood that the detailed description and specific examples, while indicating the non-limiting embodiments of the disclosure, are intended for purposes of illustration only and are not intended to limit the scope of the disclosure.

### BRIEF DESCRIPTION OF THE DRAWINGS

The present disclosure will become more fully understood from the detailed description and the accompanying drawings.

FIG. 1 depicts a housing, according to an embodiment of the disclosure.

FIG. 2a shows a first example orientation in association with the housing of FIG. 1, in accordance with an embodiment of the disclosure.

FIG. 2b shows a second example orientation in association with the housing of FIG. 1, in accordance with an embodiment of the disclosure.

FIG. 2c shows a third example orientation in association with the housing of FIG. 1, in accordance with an embodiment of the disclosure.

### DETAILED DESCRIPTION

It should be understood that like reference numerals identify corresponding or similar elements throughout the several drawings. It should be understood that although a particular component arrangement is disclosed and illustrated in these exemplary embodiments, other arrangements could also benefit from the teachings of this disclosure.

It is generally contemplated that ingress protection may possibly be provided by manner of a module (e.g., an enclosure which may encapsulate one or more electrical/electronic components) which may include an overlap configuration (e.g., by manner of a lip overlap with a cover, forming a single wall overlap). The present disclosure contemplates that such an overlap configuration may not be optimal, adequate and/or sufficient in the context of ingress protection. For example, a single wall overlap may possibly be limited in terms of water ingress protection. In a specific example, water ingress protection may be limited depending on orientation of the module (e.g., depending on the structure of the overlap configuration, water ingress protection may be more effective when the module is in an upright orientation as compared to being in an upside-down orientation), and ingress protection may be considered not to be optimal in view of such orientation dependency. Moreover, as orientation (of the module) may limit ingress protection (e.g., water ingress protection), ingress protection may be considered to be inadequate and/or insufficient in the event of, for example, a module being non-optimally oriented.

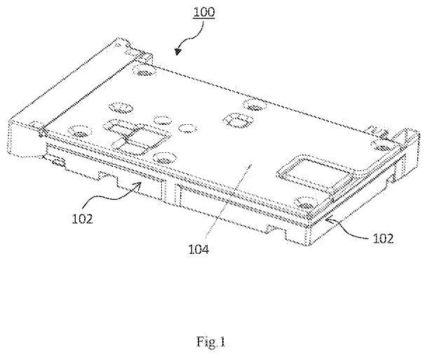

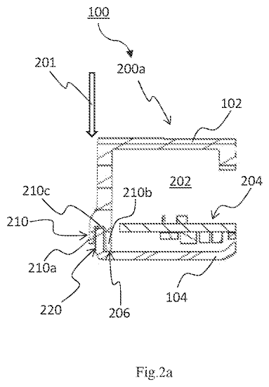

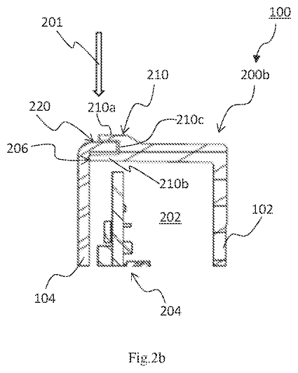

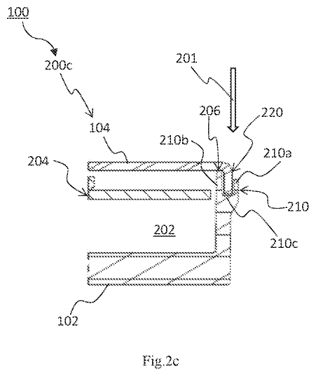

The present disclosure contemplates it would possibly be helpful to, for example, facilitate ingress protection (e.g., water ingress protection) regardless of orientation, as will be discussed in further detail with reference to FIG. 1 and FIG. 2 hereinafter.

Referring to FIG. 1 a housing 100 (e.g., referable to as a module housing) is shown, according to an embodiment of the disclosure. The housing 100 may, for example, be capable of being carried by a vehicle (not shown), in accordance with an embodiment of the disclosure.

Specifically, the housing 100 may, for example, be shaped and dimensioned in a manner so as to be capable of carrying one or more components (e.g., electrical and/or electronic component(s)), in accordance with an embodiment of the disclosure. In one embodiment, the housing 100 may, for example, correspond to an enclosure, and the component(s) may be carried in a manner so as to be contained/accommodated within the enclosure. The component(s) may, for example, be configured in connection with one or more operational requirements in association with the vehicle. In one specific example, the component(s) may be associated with/be part of/form a Telematics Control Unit (TCU), in accordance with an embodiment of the disclosure. In another specific example, the component(s) may be associated with/be part of/form an infotainment unit, in accordance with an embodiment of the disclosure. The, for example, TCU and/or infotainment unit may be carried by, for example, a vehicle, in accordance with an embodiment of the disclosure.

In accordance with an embodiment of the disclosure, the housing 100 may include one or both of at least one housing part 102 and at least one housing portion 104.

In one example the housing 100 may include the housing part(s) 102, in accordance with an embodiment of the disclosure. In another example, the housing 100 may include the housing portion(s) 104, in accordance with an embodiment of the disclosure. In yet another example, the housing 100 may include the housing part(s) 102 and the housing portion(s) 104, in accordance with an embodiment of the disclosure.

The present disclosure contemplates that, in one embodiment, the housing 100 may include the housing part(s) 102 and the housing portion(s) 104.

Generally, the housing part(s) 102 may, for example, be coupled to the housing portion(s) 104, in accordance with an embodiment of the disclosure. The housing part(s) 102 and the housing portion(s) 104 may, for example, be coupled in a manner so as to form an enclosure within which the component(s) may be carried, in accordance with an embodiment of the disclosure. The component(s) may, for example, be carried within (e.g., enclosed/accommodated within) the housing 100, in accordance with an embodiment of the disclosure. In one example, the housing part(s) 102 and the housing portion(s) 104 may be coupled in a manner such that the component(s) may be enclosed in the housing 100, in accordance with an embodiment of the disclosure.

In one example, the housing part(s) 102 may, for example, correspond to a body and the housing portion(s) 104 may, for example, correspond to a cover, in accordance with an embodiment of the disclosure. In another example, the housing portion(s) 104 may, for example, correspond to a body the housing part(s) 102 may, for example, correspond to a cover, in accordance with an embodiment of the disclosure.

The body may, for example, be shaped and dimensioned in a manner so as to be capable of carrying the component(s). Moreover, the body may be shaped and dimensioned in a manner such that an opening (e.g., for allowing access into the body) may be defined. Furthermore, the cover may, for example, be shaped and dimensioned in a manner so as to be capable of covering the opening when the body and the cover are coupled (e.g., mated). In a specific example, the body may be shaped and dimensioned in a manner so as to be capable of accommodating the component(s) within the body, and the cover may be shaped and dimensioned in a manner so as to be capable of mating with the body (e.g., covering the opening) so as to form an enclosure which may be capable of facilitating Ingress Protection.

It is contemplated that the body and the cover may, for example, be coupled (e.g., mated) in a manner so as to form an enclosure which may be capable of Ingress Protection (e.g., water Ingress Protection) regardless of orientation (e.g., orientation of the housing 100), in accordance with an embodiment of the disclosure. This will be discussed, in accordance with an embodiment of the disclosure, in further detail with reference to FIG. 2a to FIG. 2c hereinafter.

FIG. 2a shows (e.g., a cut-off view) a first example orientation 200a in association with the housing 100, in accordance with an embodiment of the disclosure. FIG. 2b shows (e.g., a cut-off view) a second example orientation 200b in association with the housing 100, in accordance with an embodiment of the disclosure. FIG. 2c shows (e.g., a cut-off view) a third example orientation 200c in association with the housing 100, in accordance with an embodiment of the disclosure. Generally, in an example context of water Ingress Protection, an arrow 201 may depict, for example, water flow in FIG. 2a to FIG. 2c, in accordance with an embodiment of the disclosure.

As discussed earlier, the housing 100 may, for example, include at least one housing part 102 (e.g., at least one body) and at least one housing portion 104 (e.g., at least one cover), in accordance with an embodiment of the disclosure. In one embodiment, a housing 100 may, for example, include a housing part 102 and a housing portion 104. The housing part 102 may, for example, be coupled to the housing portion 104, in accordance with an embodiment of the disclosure.

Referring to FIG. 2a to FIG. 2c, the housing part 102 and the housing portion 104 may be coupled in a manner so as to form an enclosure (i.e., which may correspond to the housing 100) associable with a first example orientation 200a, a second example orientation 200b and a third example orientation 200c respectively, in accordance with an embodiment of the disclosure. Moreover, the enclosure may, for example, include/be associated with an enclosed area 202. One or more components 204 (e.g., electrical and/or electronic component(s)) may, for example, be carried within the enclosure (i.e., carried within the enclosed area 202) in a manner such that Ingress Protection (e.g., water Ingress Protection) may be afforded in respect of the carried component(s) 204. Moreover, in one example, the housing 100 may, as a possible option, include at least one seal portion 206 which may possibly, for example, enhance Ingress protection, in accordance with an embodiment of the disclosure. A seal portion 206 may, for example, function/serve as a contact portion/an enhanced contact portion between the housing part 102 and the housing portion 104 (i.e., when the housing part 102 and the housing portion 104 are coupled), in accordance with an embodiment of the disclosure. In this regard, it is appreciable that, in one embodiment, contact/enhanced contact between the housing part 102 and the housing portion 104 may, for example, be established via the seal portion 206. In one example, the housing 100 may include any one of the housing part 102, the housing portion 104, and the seal portion 206, or any combination thereof (i.e., the housing part 102, the housing portion 104, and/or the seal portion 206). In one specific example, the housing 100 may include one or both of the housing part 102 and the housing portion 104 (i.e., the housing part 102 and/or the housing portion 104), in accordance with an embodiment of the disclosure. In another specific example, the housing 100 may include one or both of the housing part 102 and the housing portion 104, and the seal portion 206 (i.e., the housing part 102 and/or the housing portion 104, and the seal portion 206), in accordance with an embodiment of the disclosure. In yet another specific example, the housing 100 may include the housing part 102, the housing portion 104, and the seal portion 206, in accordance with an embodiment of the disclosure.

The housing part 102 may, for example, include at least one receiving part 210, in accordance with an embodiment of the disclosure. The housing portion 104 may, for example, include at least one mating portion 220, in accordance with an embodiment of the disclosure. For example, the receiving part 210 may be shaped and dimensioned in a manner so as to be capable of mating with the housing portion 104 when the housing part 102 is coupled with the housing portion 104. In one specific example, the receiving part 210 may be shaped and dimensioned in a manner so as to be capable of mating with the mating portion 220 when the housing part 102 is coupled with the housing portion 104. In yet a more specific example, when the housing part 102 and the housing portion 104 are coupled, the receiving part 210 may be shaped and dimensioned in a manner so as to be capable of receiving/accommodating the mating portion 220. The receiving part 210 may, for example, be considered to be a female part with respect to the mating portion 220 whereas the mating portion 220 may, for example, be considered to be a male portion with respect to the receiving part 210, in accordance with an embodiment of the disclosure.

The receiving part 210 may, for example, include/be in the form of/correspond to a channel/groove structure capable of receiving the mating portion 220, in accordance with an embodiment of the disclosure. The receiving part 210 may, for example, include a first wall structure 210a and a second wall structure 210b. The first wall structure 210a may, for example, be opposite the second wall structure 210b (e.g., the first wall structure 210a may, for example, be positionally opposite the second wall structure 210b). Moreover, the first wall structure 210a and the second wall structure 210b may, for example, be spaced apart such that an adjoining structure 210c may be defined. In this regard, it is appreciable that the first wall structure 210a, the second wall structure 210b, and the adjoining structure 210c may, for example, be considered to form the channel/groove structure, in accordance with an embodiment of the disclosure. The first wall structure 210a may, for example, be facing outside of the housing 100 whereas the second wall structure 210b may, for example, be facing the enclosed area 202, in accordance with an embodiment of the disclosure. In this regard, it is appreciable that the first wall structure 210a may, for example, be referable to as an “outer wall structure” and the second wall structure 210b may, for example, be referable to as an “inner wall structure” in accordance with an embodiment of the disclosure. Moreover, in one example, the first wall structure 210a (e.g., outer wall structure) may be of a height/length which may be shorter as compared to height/length of the second wall structure 210b (e.g., inner wall structure), in accordance with an embodiment of the disclosure.

The mating portion 220 may, for example, include/be in the form of/correspond to a protrusion (e.g., a protruding structure) shaped and dimension in a manner so as to be capable of being received by the receiving part 210, in accordance with an embodiment of the disclosure. For example, the protrusion may be shaped and dimensioned so as to be capable of being accommodated within the receiving part 210, in accordance with an embodiment of the disclosure.

Referring specifically to FIG. 2a, the first example orientation 200a may, for example, be such that the housing 100 may be considered to be resting on the housing portion 104 (e.g., a housing module which, when at rest position, may be considered to be resting on its cover), in accordance with an embodiment of the disclosure. The first example orientation 200a may, for example, be referable to as a “Module horizontal down”/“Upside down” orientation, in accordance with an embodiment of the disclosure. It is contemplated that Ingress Protection may be facilitated when, for example, water flow (i.e., as depicted by arrow 201) into the enclosure may possibly be impeded, in accordance with an embodiment of the disclosure.

Referring specifically to FIG. 2b, the second example orientation 200b may, for example, be such that the housing 100 may be considered to be resting on one or both of the housing part 102 and the housing portion 104 (e.g., a housing module which, when at rest position, may be considered to be resting on its cover and/or its body), in accordance with an embodiment of the disclosure. The second example orientation 200b may, for example, be referable to as a “Module Vertical” orientation, in accordance with an embodiment of the disclosure. It is contemplated that Ingress Protection may be facilitated when, for example, water flow (i.e., as depicted by arrow 201) into the enclosure may possibly be impeded, in accordance with an embodiment of the disclosure.

Referring specifically to FIG. 2c, the third example orientation 200c may, for example, be such that the housing 100 may be considered to be resting on the housing part 102 (e.g., a housing module which, when at rest position, may be considered to be resting on its body), in accordance with an embodiment of the disclosure. The third example orientation 200c may, for example, be referable to as a “Module horizontal up” orientation, in accordance with an embodiment of the disclosure. It is contemplated that Ingress Protection may be facilitated when, for example, water flow (i.e., as depicted by arrow 201) into the enclosure may possibly be impeded, in accordance with an embodiment of the disclosure.

It is generally contemplated that the receiving part 210 may correspond to/include/be associated with a channel structure which may possibly facilitate multi orientation-based (e.g., a first example orientation 200a, a second example orientation 200b and/or a third example orientation 200c) Ingress Protection. For example, when the receiving part 210 is coupled (e.g., mated) with the mating portion 220, multi orientation-based Ingress Protection may possibly be facilitated. Specifically, it is contemplated that in the above manner, ingress protection (e.g., water ingress protection) may possibly be facilitated regardless of orientation.

Moreover, with regard to FIG. 2a to FIG. 2c, it is earlier contemplated that the first wall structure 210a (e.g., outer wall structure) may, for example, be of a height/length which may be shorter as compared to height/length of the second wall structure 210b (e.g., inner wall structure), in accordance with an embodiment of the disclosure. It is contemplated that this may possibly enhance/improve Ingress Protection. For example, in regard to the third example orientation 200c, an outer wall structure which is shorter than an inner wall structure may possibly facilitate excess water overflow to the outside of the housing 100, in accordance with an embodiment of the disclosure (e.g., effectively an “overflow” arrangement/structure which may possibly limit retention of water in the receiving part 210, which may possibly reduce the possibility of water flow into the enclosed area 202).

The foregoing will now be discussed in further detail based on a first example implementation and a second example implementation, in accordance with an embodiment of the disclosure, hereinafter.

Regarding the first example implementation, the receiving part 210 may, for example, correspond to a channel structure which may correspond to a “U” shaped/based channel (i.e., referable to as a “U” channel). The mating portion 220 may, for example, correspond to a lip which may correspond to a protrusion formed based on an angled bend (e.g., a right-angled bend in the cover creating a lip). For example, the lip may interface with the “U” channel. In one specific example, one end (e.g., an edge) of a housing portion 104 (e.g., at least one cover) may be bent in a manner so as to form a protrusion (e.g., referable to as a “lip”) which may be capable of being recessed into the “U” channel. In one specific example, one bent end of the cover (e.g., cover lip) may be recessed into the “U” channel and direct water drip impact(s) may possibly be facilitated (e.g., an internal surface of a cover may be in contact with at least one interior side of the u channel walls which may effectively at least impede water ingress access into the enclosed area 202). It is contemplated that, in one specific example, the “U” channel may possibly provide some form of an overlap to the cover lip in various orientations (e.g., the first to third example orientations 200a/200b/200c) which may possibly facilitate protection in regard to access to the cover lip, in accordance with an embodiment of the disclosure (e.g., water flow, as depicted by arrow 201, may possibly be directed away from the cover). Moreover, the interior wall structure of the “U” channel may be shaped and dimensioned so as to be shorter than the inner wall structure so as to possibly, for example, facilitate dispensation of water (e.g., in the “Module horizontal up” orientation).

Regarding the second example implementation, the receiving part 210 may, for example, correspond to a channel structure which may correspond to a “V” shaped/based channel (i.e., referable to as a “V” channel). It is appreciable that the second example implementation may be analogous to the first example implementation with the exception of the receiving part 210 corresponding, for example, to a “V” channel instead of, for example, to a “U” channel (as discussed per the first example implementation). In this regard, relevant portions of the foregoing discussion with regard to the first example implementation may analogously apply, where appropriate, in the context of the second example implementation. For example, the mating portion 220 may, for example, correspond to a lip which may correspond to a protrusion formed based on an angled bend (e.g., a right-angled bend in the cover creating a lip) and the lip may interface with the “V” channel (e.g., in analogous manner as discussed with reference to the first example implementation).

As discussed earlier, in one example, the housing 100 may, as a possible option, include at least one seal portion 206 which may possibly, for example, enhance Ingress protection, in accordance with an embodiment of the disclosure. The seal portion 206 may, for example, function/serve as a contact portion/an enhanced contact portion between the housing part 102 and the housing portion 104 (i.e., when the housing part 102 and the housing portion 104 are coupled) so as to facilitate contact/enhanced contact between the housing part 102 and the housing portion 104. For example, the seal portion(s) 206 may be positioned/disposed at one end (e.g., at the tip) of the second wall structure 210b, in accordance with an embodiment of the disclosure.

It is contemplated that the seal portion(s) 206 has/have been discussed in the context of a possible option and may possibly be unnecessary (i.e., may be omitted) where the housing part 102 and the housing portion 104 may be coupled such that Ingress Protection may be considered to be adequate/sufficient. For example, the receiving part 210 may be shaped and dimensioned in a manner such that the mating portion 220 may be received such that interference/press-fit may be established (e.g., when the mating portion 220 is received by the receiving part 210 such that the mating portion 220 may be press-fit against the first and second wall structures 210a/210b. In a more specific example, the mating portion 220, when received by the receiving part 210, may be interference/press-fit against the internal surface(s) of the first and second wall structures 210a/210b. In yet a more specific example, when the lip may be received by the channel structure (e.g., “V” channel) such that the lip may effectively be considered to be wedged between the first and second wall structures 210a/210b. It is contemplated that where the mating portion 220 may be press-fit against the first and second wall structures 210a/210b (e.g., internal surface(s) of the first and second wall structures 210a/210b), it may be possible that adequate/sufficient Ingress Protection may be facilitated in the sense that, for example, water flow into the enclosed area 202 may be adequately/sufficiently impeded without the use/need for the seal portion(s) 206, in accordance with an embodiment of the disclosure.

In view of the foregoing, it is appreciable that there is generally contemplated, a housing 100 in accordance with an embodiment of the disclosure. The housing 100 may, for example, include at least one housing part 102 (e.g., a body) and at least one housing portion 104 (e.g., a cover), in accordance with an embodiment of the disclosure.

In a specific example, in accordance with an embodiment of the disclosure, the housing 100 may include a housing part 102 which may include a receiving part 210. The receiving part 210 may, for example, include a first wall structure 210a and a second wall structure 210b. The second wall structure 210b may be opposing (e.g., positionally opposing) the first wall structure 210a (e.g., the first wall structure 210a and the second wall structure 210b may be positioned opposite each other). Moreover, the first wall structure 210a may be shorter (e.g., based on height/length) as compared to the second wall structure 210b. The housing 100 may further include a housing portion 104 which may be coupled to the housing part 102. The housing part 102 and the housing portion 104, when coupled, may form an enclosure which may be associated with an enclosed area 202 within which one or more components 204 may be carried. The component(s) 204 may, for example, be carried in a manner such that Ingress Protection (e.g., water Ingress Protection) may be facilitated.

In one embodiment, the first wall structure 210a and the second wall structure 210b may be spaced apart such that an adjoining structure 210c may be defined. The first wall structure 210a, the second wall structure 210b, and the adjoining structure 210c may, for example, form a channel structure, in accordance with an embodiment of the disclosure. In one example, the channel structure may correspond to a “U” shaped channel. In another example, the channel structure may correspond to a “V” shaped channel. In this regard, it is appreciable that the receiving part 210 may, for example, correspond to/be associated with/include a channel structure (e.g., a “U” shaped channel/a “V” shaped channel), in accordance with an embodiment of the disclosure.

In one embodiment, the housing portion 104 may include a mating portion 220. The mating portion 220 may, for example, be shaped and dimensioned in a manner so as to be capable of being received by the receiving part 210 when the housing part (102) and the housing portion (104) are coupled. In one example, the mating portion 220 may correspond to a protrusion (e.g., a lip) which may be formed by manner of an angled bend along at least a portion of the housing portion 104 (e.g., a right-angled bend along an edge/an end of the housing portion 104, forming a lip), in accordance with an embodiment of the disclosure.

In one embodiment, the mating portion 220 may, for example, engage (e.g., by manner of being wedged) one or both of the first wall structure 210a and the second wall structure 210b (i.e., the first wall structure 210a and/or the second wall structure 210b) by manner of press-fit/interference-fit. For example, the mating portion 220 may be received by the receiving part 210 in a manner such that contact may be established by manner of press-fit/interference-fit. In one example, the mating portion 220 may engage (e.g., contact being established) the channel structure by manner of press-fit/interference-fit. In a specific example, the mating portion 220 may engage at least the first wall structure 210a and the second wall structure 210b by manner of interference-fit (e.g., contact may be established between the mating portion 220 and, at least the first wall structure 210a and the second wall structure 210b by manner of interference-fit).

In one embodiment, the housing 100 may further include a seal portion 206 via which contact between the housing part 102 and the housing portion 104 may be established. In one example, the seal portion 206 may be carried by the second wall structure 210b. In a more specific example, the seal portion 206 may be carried at one end of the second wall structure 210b.

Further in view of the foregoing, it is appreciable that there is generally contemplated, an apparatus in accordance with an embodiment of the disclosure. The apparatus may, for example, correspond to/include/be associated with the aforementioned housing part 102, in accordance with an embodiment of the disclosure. In one embodiment, the apparatus may correspond to the aforementioned housing part 102 (e.g., the housing part 102 may possibly be referred to as an “apparatus” in accordance with an embodiment of the disclosure).

The apparatus (e.g., a body) may, for example, be used with a housing portion 104 (e.g., a cover). In one specific example, the apparatus may be coupled with the housing portion 104 in a manner so as to form an enclosure which may, for example, include/be associated with an enclosed area 202. One or more components 204 may, for example, be carried within the enclosure (i.e., carried within the enclosed area 202) in a manner such that Ingress Protection (e.g., water Ingress Protection) may be afforded in respect of the carried component(s) 204. The housing portion 104 may, for example, include a mating portion 220. The mating portion 220 may, for example, correspond to a protrusion (e.g., a lip), in accordance with an embodiment of the disclosure. The apparatus may, for example, include a receiving part 210 which may be shaped and dimensioned in a manner so as to be capable of receiving the mating portion 220 when coupled with the housing portion 104.

Generally, the present disclosure contemplates, in one embodiment, an apparatus which may be used with a housing portion 104 to form an enclosure. The enclosure may be associated with an enclosed area 202. Moreover, the housing portion 104 may, for example, include one or more protrusions (e.g., at least one lip). The apparatus may include a receiving part 210 shaped and dimensioned in a manner so as to be capable of receiving the protrusion (e.g., a lip) when the apparatus and the housing portion 104 are coupled.

The receiving part 210 may, for example, include a first wall structure 210a and a second wall structure 210b. The first wall structure 210a and the second wall structure 210b may, for example, be spaced apart in a manner so as to define an adjoining structure 210c. Furthermore, the first wall structure 210a may, for example, be shorter (e.g., in terms of height/length) as compared to the second wall structure 210b, in accordance with an embodiment of the disclosure.

In this regard, it is generally contemplated that the enclosure may be shaped and dimensioned in a manner so as to carry one or more components 204 within the enclosed area 202. The component(s) 204 may be carried in the enclosed area 202 such that Ingress Protection (i.e., in association with the component(s) 204 carried within the enclosed area 202) may be facilitated, in accordance with an embodiment of the disclosure. Ingress Protection may, for example, be in relation to at least water Ingress Protection, in accordance with an embodiment of the disclosure.

In one embodiment, the first wall structure 210a, the second wall structure 210b and the adjoining structure 210c may form a channel structure. For example, a channel structure may be formed based on the first wall structure 210a, the second wall structure 210b and the adjoining structure 210c. In one example, the channel structure may correspond to a “U” shaped channel. In another example, the channel structure may correspond to a “V” shaped channel. In this regard, it is appreciable that the receiving part 210 may, for example, correspond to/be associated with/include a channel structure (e.g., a “U” shaped channel/a “V” shaped channel), in accordance with an embodiment of the disclosure.

In one embodiment, the second wall structure 210b may, for example, be shaped and dimensioned in a manner so as to be capable of carrying a seal portion 206. For example, the second wall structure 210b may include an end (e.g., a tip), and the seal portion 206 may, for example, be being carried at the tip of the second wall structure 210b. In one example, when the protrusion has been received by the receiving part 210, contact may be established between the second wall structure 210b and the housing portion 104 via the seal portion 206. In one example, when the protrusion has been received by the receiving part 210, contact may be established between the second wall structure 210b and the housing portion 104 via the seal portion 206.

In one embodiment, the protrusion may, for example, engage one or both of the first wall structure 210a and the second wall structure 210b (i.e., the first wall structure 210a and/or the second wall structure 210b) by manner of press-fit/interference-fit. For example, the protrusion may be received by the receiving part 210 in a manner such that contact may be established by manner of press-fit/interference-fit. In one example, the protrusion may engage (e.g., contact being established) the channel structure by manner of press-fit/interference-fit. In a specific example, the protrusion may engage at least the first wall structure 210a and the second wall structure 210b by manner of interference-fit (e.g., contact may be established between the protrusion and, at least the first wall structure 210a and the second wall structure 210b by manner of interference-fit). Generally, when the protrusion has been received by the receiving part 210, contact may, for example, be established between the protrusion and the receiving part 210 by manner of interference-fit. In one example, interference-fit/press-fit may be in a manner such that contact may be established between protrusion and the receiving part 210 such that the protrusion is wedged between the first wall structure 210a and the second wall structure 210b.

It should be appreciated that the embodiments described above may be combined in any manner as appropriate (e.g., one or more embodiments as discussed in the “Detailed Description” section may be combined with one or more embodiments as described in the “Brief Summary” section).

It should be further appreciated by the person skilled in the art that variations and combinations of embodiments described above, not being alternatives or substitutes, may be combined to form yet further embodiments.

In one example, earlier mentioned, the seal portion 206 may be carried by the second wall structure 210a. It is contemplated that the seal portion 206 may possibly be carried by the housing portion 104 (i.e., instead of the second wall structure 210a) at a position coinciding with the second wall structure 210a when the housing part 102 and the housing portions 104 are coupled.

In another example, it is contemplated that the seal portion 206 may possibly be carried by both the second wall structure 210a and the housing portion 104 (e.g., one part of the seal portion 206 may be carried by the second wall structure 210a and another part of the seal portion 206 may be carried by the housing portion 104).

In yet another example, it is contemplated that one or more seal portions 206 may be carried by the housing part 102 (e.g., a first seal portion being carried at one end of the second wall structure 210a and a second seal portion being carried at a side of the second wall structure 210a), in accordance with an embodiment of the disclosure.

In yet another example, a housing method (not shown) in association with the housing 100 may be provided, in accordance with an embodiment of the disclosure. The housing method may, in one embodiment, include providing any one of the housing part 102, the housing portion 104 and the seal portion 206, or any combination thereof. The housing method may, in one example, further include assembling any one of the housing part 102, the housing portion 104, and the seal portion 106, or any combination thereof, in a manner so as to form the housing 100, in accordance with an embodiment of the disclosure.

The foregoing description shall be interpreted as illustrative and not be limited thereto. One of ordinary skill in the art would understand that certain modifications may come within the scope of this disclosure. Although the different non-limiting embodiments are illustrated as having specific components or steps, the embodiments of this disclosure are not limited to those combinations. Some of the components or features from any of the non-limiting embodiments may be used in combination with features or components from any of the other non-limiting embodiments. For these reasons, the appended claims should be studied to determine the true scope and content of this disclosure.

1. An apparatus usable with a housing portion to form an enclosure associable with an enclosed area, the housing portion comprising at least one protrusion, the apparatus comprising:
a receiving part shaped and dimensioned in a manner so as to be capable of receiving the protrusion when the apparatus and the housing portion are coupled, the receiving portion comprising:
a first wall structure; and
a second wall structure, the first wall structure and the second wall structure being spaced apart in a manner so as to define an adjoining structure,
wherein the first wall structure is shorter as compared to the second wall structure.

2. The apparatus according to claim 1, the enclosure being shaped and dimensioned in a manner so as to carry at least one component within the enclosed area in a manner so as to facilitate Ingress Protection in association with the component carried.

3. The apparatus according to claim 1, wherein the first wall structure, the second wall structure, and the adjoining structure form a channel structure.

4. The apparatus according to claim 3, wherein the channel structure corresponds to a “U” shaped channel.

5. The apparatus according to claim 3, wherein the channel structure corresponds to a “V” shaped channel.

6. The apparatus according to claim 1, wherein the second wall structure is shaped and dimensioned in a manner so as to be capable of carrying a seal portion.

7. The apparatus according to claim 6, wherein the second wall structure comprises a tip at which the seal portion is capable of being carried.

8. The apparatus according to claim 7, wherein when the protrusion has been received by the receiving part, contact is established between the second wall structure and the housing portion via the seal portion.

9. The apparatus according to claim 1, wherein, when the protrusion has been received by the receiving part, contact is established between the protrusion and the receiving part by manner of interference-fit.

10. The apparatus according to claim 9, wherein contact is established between the protrusion and the receiving part such that the protrusion is wedged between the first wall structure and the second wall structure.

11. A housing comprising:
a housing part comprising a receiving part, the receiving part comprising:
a first wall structure; and
a second wall structure opposing the first wall structure,
wherein the first wall structure is shorter as compared to the second wall structure; and
a housing portion capable of being coupled to the housing part, the housing part and the housing portion when coupled forming an enclosure associable with an enclosed area within which at least one component is capable of being carried in a manner such that Ingress Protection is capable of being facilitated.

12. The housing according to claim 11, the first wall structure and the second wall structure being spaced apart such that an adjoining structure is capable of being defined.

13. The housing according to claim 12, the first wall structure, the second wall structure and the adjoining structure forming a channel structure.

14. The housing according to claim 13, wherein the channel structure corresponds to a “U” shaped channel.

15. The housing according to claim 13, wherein the channel structure corresponds to a “V” shaped channel.

16. The housing according to claim 11, the housing portion comprising a mating portion shaped and dimensioned in a manner so as to be capable of being received by the receiving part when the housing part and the housing portion are coupled.

17. The housing according to claim 16, the mating portion corresponding to a protrusion formed by manner of an angled bend along at least a portion of the housing portion.

18. The housing according to claim 16, the mating portion capable of engaging at least the first wall structure and the second wall structure by manner of interference-fit.

19. The housing according to claim 11, further comprising a seal portion via which contact between the housing part and the housing portion is capable of being established.

20. The housing according to claim 18, the seal portion capable of being carried by the second wall structure.
